(19) United States
(12) Patent Application Publication
(10) Pub. No.: US 2006/0035474 A1
(43) Pub. Date: Feb. 16, 2006

(54) Increasing retention time for memory devices

(76) Inventors: Pavel Komilovich, Corvallis, OR (US); James Stasiak, Lebanon, OR (US)

Correspondence Address: HEWLETT-PACKARD DEVELOPMENT COMPANY, Intellectual Property Administration, P.O. Box 272400, Fort Collins, CO, 80527-2400, US

(21) Appl. No.: 10/914,827

(22) Filed: Aug. 10, 2004

(51) Int. Cl. H01L 21/31; H01L 51/40; H01L 21/82; H01L 21/00

(52) U.S. Cl. 438/780; 438/99; 438/82; 438/129; 438/128

(57) ABSTRACT

This disclosure relates to a doped polymer memory device. In one aspect the doped polymer memory device includes a molecularly doped polymer layer that includes a binder and a dopant. The combination of the binder and the dopant modifies polarizability of the molecularly doped polymer layer in a manner that enhances the retention time of the doped polymer memory device. In another aspect, the doped polymer memory device includes a molecularly doped polymer layer that includes a binder and a dopant. An additional dopant is added to the molecularly doped polymer layer. The additional dopant is selected to modify polarizability of the molecularly doped polymer layer in a manner that enhances the retention time of the doped polymer memory device.

### TECHNICAL FIELD

This disclosure relates to memory devices, and more particularly to increasing retention time for memory devices.

### BACKGROUND

Memory device design and construction (including capacitors and certain transistors) often involves balancing many competing parameters such as the amount of data stored, the density of the data storage, reliability, speed, expense, operation under adverse conditions, the reliability of data storage, and the retention time. Retention time measures the duration that the memory device retains its state after the bit has been written (i.e., following a transition from a low state to a high state or vice versa).

Some memory devices use trapped electric charge to store digital information. Many such memory devices have a relatively brief retention time. The reliability, operation, and acceptance of these devices would benefit from increasing their retention time. There is therefore a need for enhancing the retention time for charge trapping in memory devices.

### BRIEF DESCRIPTION OF THE DRAWINGS

The same numbers are used throughout the drawings to reference like features and components.

FIG. 1 is a cross-sectional view of an exemplary doped polymer memory device.

FIG. 2 is a perspective view of another version of an array including multiple doped polymer memory devices.

FIG. 3 is a cross-sectional view of a portion of one of the doped polymer memory devices shown in FIG. 2.

FIG. 4 is a chemical diagram of an exemplary binder.

FIG. 5 is a chemical diagram of another exemplary binder.

FIG. 6 is a chemical diagram of an exemplary molecular dopant.

FIG. 7 is a chemical diagram of another molecular dopant.

FIG. 8 is a chemical diagram of yet another molecular dopant.

FIG. 9 is a cross-sectional view of another exemplary doped polymer memory device.

FIG. 10 is a cross-sectional view of another exemplary doped polymer memory device.

FIG. 11 is a graph of a plurality of memory actions applied to an embodiment of doped polymer memory device.

FIG. 12 is a graph of one embodiment of the polarization current as a function of time of the doped polymer memory device.

FIG. 13 is a block diagram of an exemplary computer system.

FIG. 14 is a perspective view of an imaging device including a doped polymer memory device.

FIG. 15 illustrates a flow chart of designing an exemplary molecularly doped polymer layer of a doped polymer memory device.

### DETAILED DESCRIPTION

Doped polymer memory devices 100 show promise as one embodiment of relatively inexpensive charge and/or data storage mechanism (that can be used as a memory) that can store a large volume of data for such applications as imaging, digital processing, and communications. Exemplary doped polymer memory devices whose retention time may be desired to be increased as described herein include, but are not limited to, memory devices, tunable capacitors, tunable resistors, and transistors.

The dimensions of the attached figures are not to scale within the figures, and certain relative dimensions may be exaggerated. The doped polymer memory devices 100 as described herein may range from quite large devices down to, and including, nanoscale devices. The doped polymer memory devices may be configured either as discrete components or integrated circuits.

Many embodiments of doped polymer memory devices as described herein rely on the trapping ability of the dopant to trap electric charges and thereby enhance the retention time. While trapped on a dopant molecule, the energy of the carrier is lower than the energy of the conducting states of the host polymer. The carrier can be displaced from its position by temperature fluctuations, which leads to a finite retention time of the memory device. The rate of this process is determined by the temperature and the energy difference between the trap and conducting states. Therefore, the immobility of the carrier is regulated by the difference of electron (or hole) affinities between the dopant molecules and the host polymer. The retention time of the doped polymer memory devices is therefore at least partially determined by the chemical composition and energy structure of the dopant and the polymer.

In general, the retention time increases when the energy of the carrier in a trap decreases. (This leads to an increase in the energy difference that regulates the temperature-activated detrapping process.) Therefore, one technique to increase the retention time involves engineering the material to substantially lower the energy of the carrier after the carrier is trapped.

Certain definitions are provided within this disclosure. A dipole moment for a charged body is the sum for all of the electric charges in a charged body of the product of the magnitude of the electric charges multiplied by the distance for each respective charge from a point of reference. For an electrically neutral system (in which the magnitude of the positive charges are equal to and opposite the magnitude of the negative charges) such as with doped polymer memory devices, the selection of the point of reference is arbitrary and does not effect the final dipole moment result. Assuming that the molecules possess individual dipole moments (which are randomly oriented in space), the overall dipole moment can be a measure of their orientation as a function of an external field.

The electrical polarization is a measure of the dipole moment of a unit volume of the medium. One embodiment of polarization can be induced by an electric field that exists in the medium. In the absence of the electric field, the polarization is zero. If a non-zero field is created in the medium, it induces a non-zero polarization, which is normally proportional to the magnitude of the field.

Polarizability of the medium is defined as the coefficient between the field and polarization. The higher the polarizability, the larger polarization will be created by the same electric field. Polarizability is a strong function of the chemical composition of the medium.

Mobility of the carriers is defined as the proportionality coefficient between the average drift velocity of the carrier and an external electric field that causes the drift. Carrier mobility is a strong function of the chemical composition of the medium. Mobility and polarizability are related. In general, the higher the polarizability, the lower the carrier mobility. Therefore, carrier mobilities can serve as indirect measures of the polarizability of molecularly doped polymers.

One way to increase the retention time of a molecularly doped polymer is to increase the polarizability of the medium. A carrier trapped on a dopant molecule creates an electric field around itself. In response to the field, the medium polarizes and in turn lowers the energy of the trapped carrier. The higher the polarizability, the more the carrier energy will be reduced, resulting in an increase in retention time.

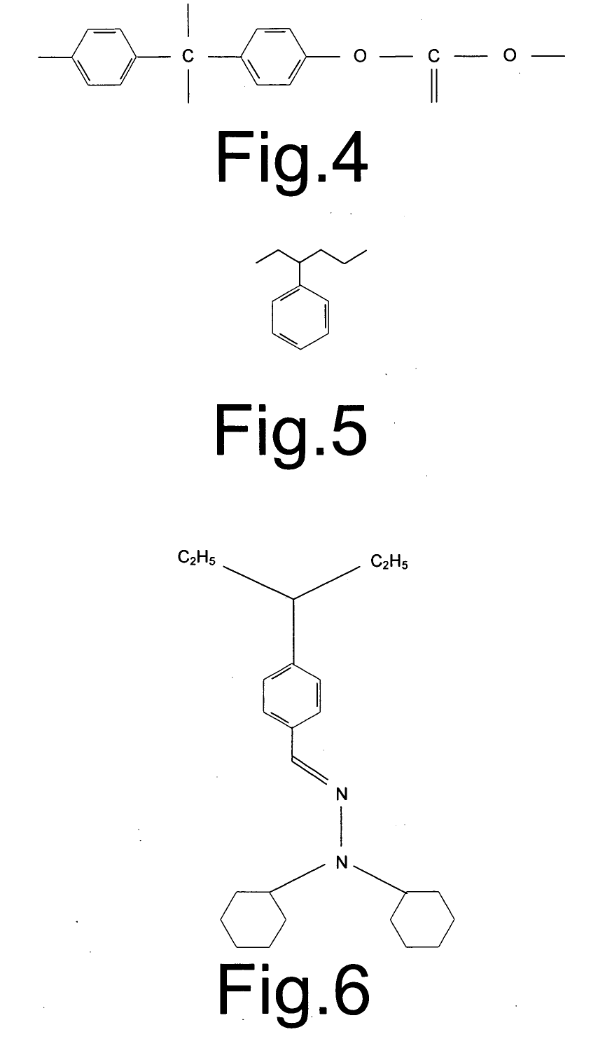

In one embodiment of the present disclosure, the polarizability of a molecularly doped polymer is increased by modifying the host polymer. In particular, the polarizability is increased by adding additional side groups to the polymer chain, which by themselves possess substantial dipole moments. These side groups can attach to the polymer molecule via a single sigma-bond to allow relatively easy rotation of the attached side group with respect to the polymer. The single sigma-bond has a low rotational energy barrier. In the presence of a charged carrier nearby, the dipole moments will therefore respond to the electric field of the carrier. As a result, the side groups will rotate and/or bend, thereby lowering the energy of the carrier and effectively trapping it. Examples of polymer binders that possess such polar side groups are polycarbonate as illustrated in FIG. 4 or polystyrene as illustrated in FIG. 5.

As an actual example, it has been observed that the effective hole mobility of diethylamino-benzaldehyde diphenyl hydrazone (DEH) (see FIG. 6) doped into polycarbonate (a polymer binder with a significant dipole moment, see FIG. 4) is lower than the hole mobility of diethylamino-benzaldehyde diphenyl hydrazone (DEH) doped at the same concentration into polystyrene (a binder with a very small dipole moment, see FIG. 5). In general, it is desired to maximize the retention time that correlates to the time during which the doped polymer memory device 100 can hold a charge (referred to herein as retention time). One indirect technique illustrates that the mobile charge is trapped more effectively by modifying the material. An article by Schein et al., entitled “Hole mobilities in hydrazone-doped polycarbonate and poly(styrene)”, Chemical Physics 177, pp 773-781 (1993) compares the mobility of charge in two molecularly doped films. In both samples, the films were doped with 10% (percentage by weight) of the molecule DEH. One sample used polycarbonate as a binder and the other used poly(styrene) as the binder. Polycarbonate has a substantial dipole moment while (poly)styrene has a near zero dipole moment.

One might expect that DEH doped into a binder with a large dipole moment would have a relatively low mobility. The mobile charge is “impeded” by the presence of a large dipolar background. This assumption is supported by the data of the article. The polycarbonate binder has a dramatic effect on the mobility. At 600 (V/cm)1/2, the mobility including a polystyrene binder is approximately 1×10-7 cm²/Vs and the mobility including a polycarbonate binder at 600 (V/cm)1/2 is approximately 1×10-9 cm²/Vs. Using the polystyrene binder results in a two orders of magnitude improvement in mobility compared to using the polycarbonate binder alone.

In an alternate embodiment of the present disclosure, the polarizability of a molecularly doped polymer is increased by introducing a second dopant molecule that has strong dipole moments into the molecularly doped polymer. In the presence of a charged carrier, certain molecules within the molecularly doped polymer layer 114 will rotate in space as a whole, again lowering the energy of the carrier and substantially increasing its trapping time. With this introduction, an increase in the retention time is provided by the second dopant molecules instead of the binder. Since different amounts of the additional molecule can be added, the retention time can thereby be “tuned” by controlling the amount and type of the second dopant molecules.

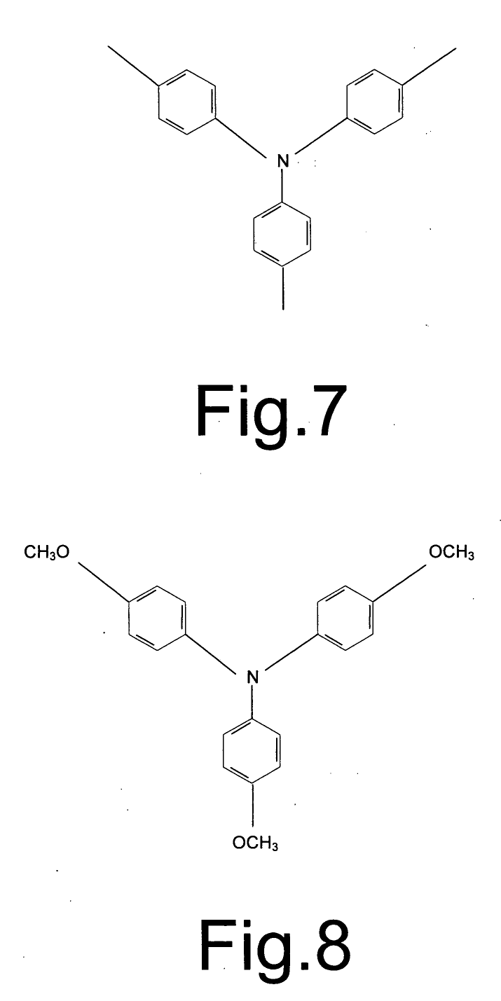

Examples of such dopants are diethylamino-benzaldehyde diphenyl hydrazone (DEH) as shown in FIG. 6 and tri-p-anisylamine (TM) as shown in FIG. 8, the latter having a relatively high dipole moment. Another material, tri-p-tolylamine (TTA) as shown in FIG. 7 has a smaller dipole moment, which when doped into polystyrene yields much higher hole mobility than TAA (molecule with a significant dipole moment) doped at the same concentration. Such selecting of a dopant with a higher or lower dipole moment to increase or decrease the retention time in a doped polymer memory device provides one aspect of the present disclosure.

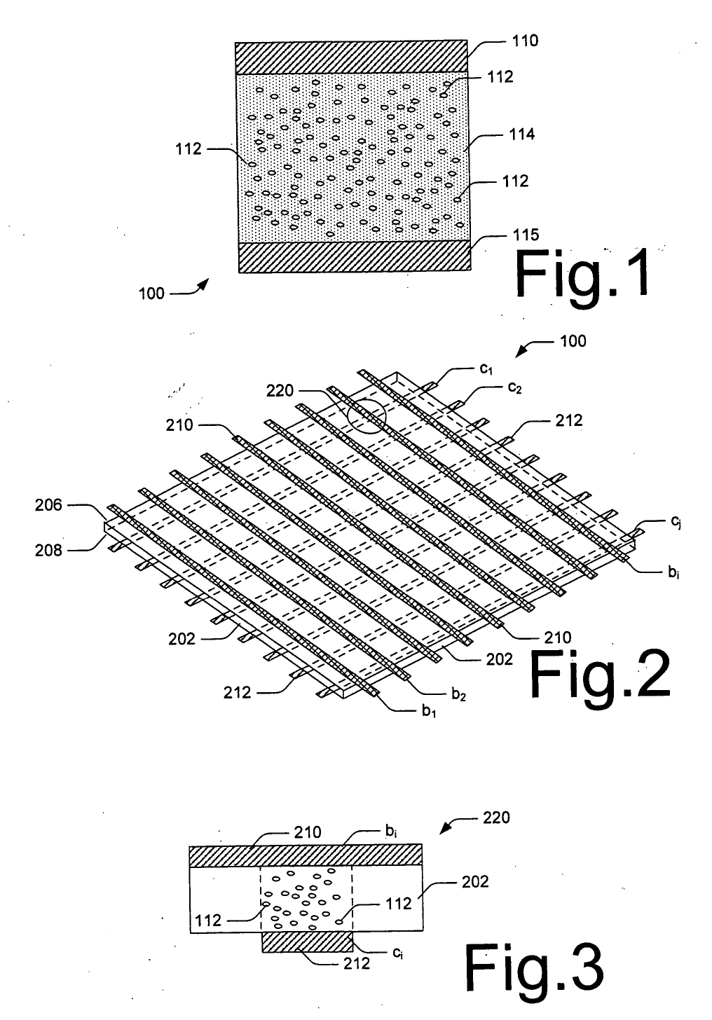

One embodiment of a memory device utilizing molecularly doped polymers is shown in FIG. 1. The doped polymer memory device 100 includes a first electrode 110, a second electrode 115, and a molecularly doped polymer layer 114. The molecularly doped polymer layer 114 is in electrical communication with and is positioned relative to (in certain versions between) the first electrode 110 and the second electrode 115. The molecularly doped polymer layer 114 includes a plurality of dopant material sites 112 (that are dispersed throughout the molecularly doped polymer layer). The dopant material sites 112 each act as a receptor site for electrons or holes in a manner generally known in semiconductor technologies to allow the electrons or holes to traverse the molecularly doped polymer layer 114 when the electrodes 110, 115 are biased. During such biasing of the electrodes 110, 115, electrons and holes can traverse the molecularly doped polymer layer 114 using a mechanism of hopping from one dopant material sites 112 to another dopant material sites across the thickness of the molecularly doped polymer layer 114.

In accordance with aspects of the present disclosure, the trapping ability of the molecularly doped polymer layer is enhanced either by appropriate modification of the polymer binder, or by introducing a second dopant.

FIG. 2 shows a perspective view of another embodiment of the doped polymer memory device 100. The parallel plate capacitor structure as described relative to FIG. 1 is configured as one cross-point within a cross-bar system. The molecularly doped polymer layer 202 in the doped polymer memory device 100 (that may be configured as a polymer film) forms a layer that can include an organic dopant (or an inorganic dopant in certain embodiments). A plurality of electrical conductors 210 are formed and are denoted as b₁ to bᵢ along the first side 206 of the molecularly doped polymer layer 202. Electrical conductors 210 are substantially parallel to each other. A plurality of electrical conductors 212 are substantially parallel to each other and are substantially mutually orthogonal to electrical conductors 210 on the second side 208 of the molecularly doped polymer layer 202. The electrical conductors 212 are denoted as c₁ to cⱼ (that are spaced along a different side from the side of the electrical conductors 210).

The combination of electrical conductors 210 and 212 form a planar orthogonal x, y matrix. A logic cell 220 is located in the volume of the molecularly doped polymer layer 202 between any two intersecting electrical conductors that form a doped polymer memory device. An array of dynamic logic cells are thereby formed between all of the pairs of overlapping electrical conductors 210 and 212. The embodiment of logic cell as described relative to FIG. 2 is structurally similar to the embodiment of parallel plate capacitor as described relative to FIG. 1. A commonly assigned application entitled “Memory Device Having A Semiconducting Polymer Film”. Ser. No. 10/171738, invented by James Stasiak, and filed on Jun. 14, 2003 (incorporated herein by reference) describes multiple embodiments of doped polymer memory devices, including the structure, dopants, binders, and components thereof.

FIG. 3 is a cross-sectional view of the logic cell 220 forming a doped polymer memory device 100 as described relative to FIG. 2. As shown in FIG. 3, the dopant material sites 112 (the dopant is organic in one version) is added to a binder material in the range from about 0.01 weight percent to about 70 weight percent, particularly from about 10 weight percent to about 50 weight percent, and more particularly from about 20 weight percent to about 40 weight percent. The thickness of the molecularly doped polymer layer 202 is in the range from about 0.01 micrometers to about 25 micrometers and more particularly in the range from about 0.01 micrometers to about 12 micrometers. The particular thickness of the molecularly doped polymer layer 202 will depend upon the electrical characteristics desired and the particular application of the doped polymer memory device.

There are a variety of exemplary dopants and binders that can be applied to the molecularly doped polymer layer 114 to form the doped polymer memory device 100. The binder (or matrix polymer) for the molecularly doped polymer layer 202 may be selected from a wide range of polymers such as polycarbonate, polystyrene, polyester, polyimide, polyvinylchloride, polymethylmethacrylate, polyvinyl acetate, vinylchloride/vinylacetate copolymers, acrylic resin, polyacrylonitrile, polyamide, polyketones, polyacrylamide, and other similar materials. The material chosen for the binder will depend on the particular electrical characteristics desired (e.g., improving the retention time), processing conditions, as well as the environmental conditions in which the device will be utilized. In one specific embodiment, the binder material is a bisphenol-A-polycarbonate with a number average molecular weight (Mn) in the range from about 5,000 to about 50,000, and more particularly from about 30,000 to about 35,000 and a polydispersity index of below about 2.5.

The dopant material that is contained within the dopant material sites 112 may contain either electron donor or electron acceptor molecules, or functional groups, or a mixture of both in a polymer host or binder. In an alternate embodiment, the molecularly doped polymer layer 202 may include separate electron donor and electron acceptor layers. The dopant material sites 112 may provide trapping sites for injected charge.

Charge transport, in the form of hole or electron transport, may thus occur between adjacent donor or acceptor molecules, respectively. Such a process can be described as a one-electron oxidation or reduction process between neutral functional groups and their charged derivatives. The transport processes, in the molecularly doped polymer layer 202, will depend on the dopant molecule or functional group, the dopant concentration, the temperature, the applied external electric field, and the polymer host or binder material. The particular molecule or functional group utilized will depend on the particular electrical characteristics desired for doped polymer memory device 100, as well as the application in which the particular doped polymer memory device will be used. The electron donor or acceptor functional groups of the present disclosure can be associated with a dopant molecule, pendant groups of a polymer, or the polymer main chain itself.

Examples of dopant molecules or functional groups within the dopant material sites 112 include, but are not limited to, various arylalkanes, arylamines including diarylamines and triarylamines, benzidine derivatives such as N,N,N′,N′,-tetrakis(4-methylphenyl)-benzidine or N,N′-Di(naphthalene-1-yl)-N,N′-diphenyl-benzidine, enamines, pyrzoline derivatives such as 1-phenyl-3-(pdiethylamino-styryl)-5-(p-diethylamino-phyenyl)-pyrazolin or 1-phyenyl-3-(2-10 chloro-styryl)-5-(2-chloro-phyenyl)-pyrazolin, hyrdazones, oxidiazoles, triazoles, and oxazoles. In addition, compounds such as 1,1-Bis(4-bis(4methylphenyl)aminophenyl)cyclohexane, Titanium (IV) oxide phthalocyanine, and other metal or metal oxide complexed phthalocyanines such as copper or vandium (IV) oxide may also be utilized.

Further, polymers such as poly(N-vinylcarbazole), poly4-[diphenylaminophenyl)methylmethacrylate], poly[(Nethylcarbazolyl-3-yl)methyl acrylate], poly(N-epoxypropylcarbazole), poly[3-carbazolyl-9-yl)propyl]methylsiloxane, polysilylenes, and polygermylenes can also be utilized as dopants. Other molecules or functional groups that may be utilized as dopants in this embodiment, include various fluorenone derivatives such as 2,4,7trinitro-9-fluorenone or n-butyl-9-dicayanomethylenefluorenone-4-carboxylate, diphenoquinones, sulfones, anthraquinones, and oxadiazoles. The particular molecule chosen will depend, for example, on the particular electronic properties desired such as whether an electron donor or electron acceptor dopant is desired. For example, various arylalkanes, arylamines, or hydrazones can be utilized as donor dopants, whereas various fluorenone derivatives can be utilized as acceptor dopants.

Electrical conductors 210 and 212 may be formed from a metal. In one embodiment, the electrical conductors 210 and 212 are configured as the electrodes 110 and 115 described relative to FIG. 1. It is envisioned that different embodiments of the doped polymer memory devices 100 may include one, or a plurality of electrodes. Examples of metals that can be utilized as electrical conductors 210 and 212 include gold, chromium, aluminum, indium, tin, lead, antimony, platinum, titanium, tungsten, tantalum, silver, copper, molybdenum, and similar metals as well as combinations thereof. In another embodiment, electrical conductors 210 and 212 may also be formed from conductive materials such as polyaniline, polypyrrole, pentacene, anthracene, napthacene, phenanthrene, pyrene, thiophene compounds, tetrathiafulvalene derivatives such as Bis-cyclohexyl-tetrathiafulvalene, or 4,4′-Diphenyl-tetrathiafulvalene, conductive ink, and similar materials.

The material chosen for the electrical conductors will depend on the particular electrical characteristics desired, processing conditions, as well as the environmental conditions in which the device will be utilized. For some applications, the electrical conductors are formed from polyaniline or thiophene compounds such as poly (3,4-ethylene dioxythiophene) (PEDOT) or camphorsulfonic acid doped polyaniline. The thickness of the electrical conductors is in the range from about 0.01 micrometers to about 1.0 micrometer, however, depending upon characteristics desired both thicker and thinner contacts may be utilized. In an alternate embodiment, electrical conductors 210 may be formed from a substantially optically transparent electrically conductive material such as indium tin oxide. Such conductors provide for programming, interrogating, and erasing the data stored in logic cells 220 via exposure to light, which will be described in greater detail below.

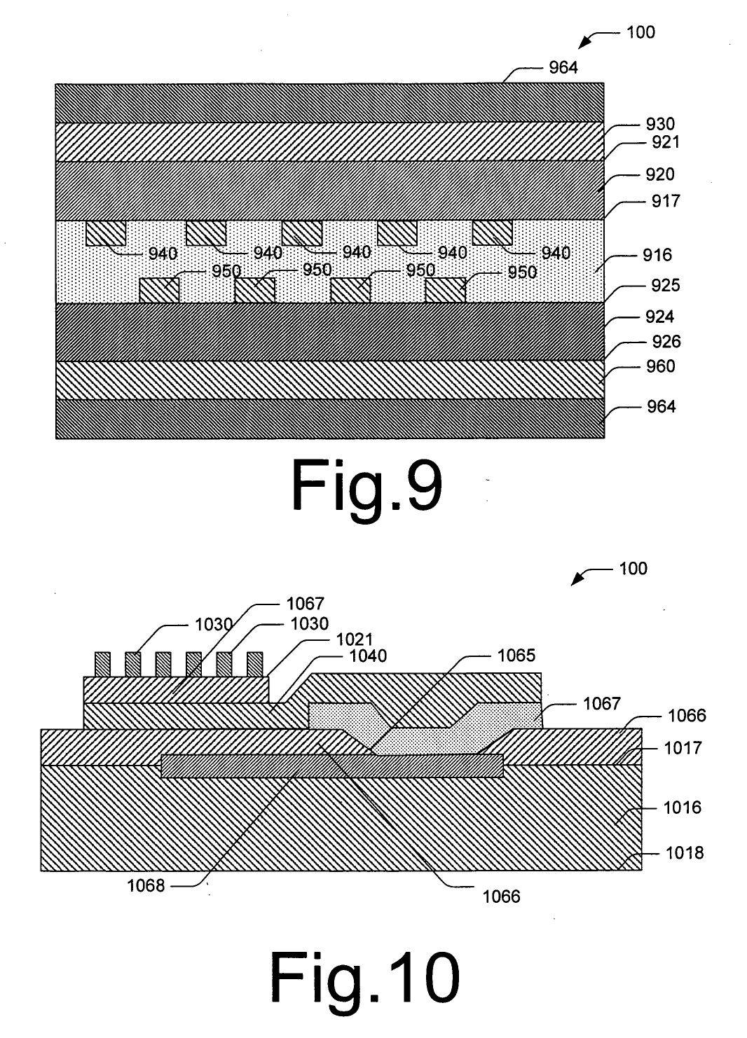

There are a number of other embodiments of the doped polymer memory devices 100 (and associated memory array configurations that include the doped polymer memory devices) that are within the intended scope of the present disclosure. One alternate embodiment of the doped polymer memory device 100 is shown in FIG. 9. In this embodiment, two molecularly doped polymer films or layers 920 and 924 are created on a substrate 916. In another embodiment, multilayers of molecularly doped polymer film may also be utilized, depending on the application and particular electrical characteristics desired, as well as the environmental conditions to which the device will be subjected. In alternate embodiments, a single layer of molecularly doped polymer layer disposed over a substrate may also be utilized. The combination of electrical conductors 930, 940, 950, and 960 form a substantially three dimensional orthogonal x, y, z matrix. Such a multilayer device architecture, using traditional lithographic technologies for patterning and creating the electrical conductors, provides on the order of 5.0 Gbits/cm² of electronic or larger depending on the number of layers used and the dimensions of the device components. Patterning of molecularly doped polymer layers 920 and 924 is not required to achieve this bit density.

The molecularly doped polymer layer 920 is disposed over a first substrate side 917 with electrical conductors 940 disposed on substrate 916 and electrically coupled to second side 922 of molecularly doped polymer layer 920. Electrical conductors 930 are electrically coupled to first side 921 of molecularly doped polymer layer 920. Electrical conductors 950 are disposed on second substrate side 918 and electrically coupled to first side 925 of molecularly doped polymer layer 924. Electrical conductors 960 are electrically coupled to second side 926 of the molecularly doped polymer layer 924. Electrical conductors 930, 940, 950, and 960 may be created from any of the metals or conductive materials, as described above, for the embodiment shown in FIG. 9. In one exemplary version, electrical conductors 940 and 950 may be formed from tantalum and electrical conductors 930 and 960 may be formed from polyaniline. In other versions, the electrical conductors may utilize all metals or all organic conductors or any combination thereof.

Referring to FIG. 10, an alternate embodiment of the doped polymer memory device 100 of the present disclosure is shown in a cross-sectional view that includes a transistor. In this embodiment, molecularly doped polymer layer 1020 forms a layer that includes an organic dopant (not shown) that is electrically coupled to one or more transistors 1068. In this embodiment, substrate 1016 is a silicon wafer having a thickness in one embodiment of about 300-700 micrometers. Using conventional semiconductor processing equipment, known to those skilled in the art, transistors 1068 as well as other logic devices required for the doped polymer memory device 100 are formed on substrate 1016. Transistors and other logic devices such as diodes may also be utilized, either separately or in combination, with the one or more doped polymer memory devices 100. Transistors 1068 are represented as a single layer in FIG. 10 to simplify the drawing.

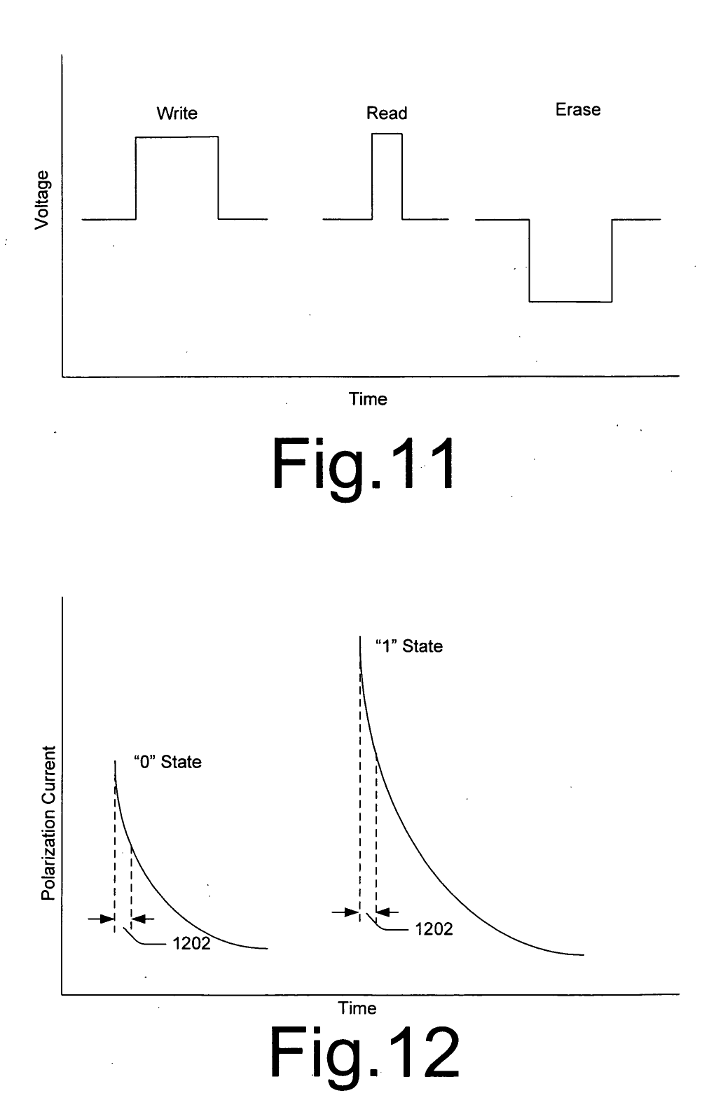

Referring to FIG. 11, a graph is shown illustrating various voltage pulses applied to the doped polymer memory device 100, according to one embodiment of the present disclosure, to perform a variety of charge storage functions such as might be used in a memory device, a capacitor device, or other memory devices. As described relative to FIG. 11, the voltage level and the duration of electronic pulses can be altered to provide different electronic functions relative to the doped polymer memory device 100.

There are three memory functions that are illustrated from left to right as illustrated in FIG. 11: “write”, “read”, and “erase” to such doped polymer memory devices 100 (certain embodiments as shown in FIGS. 1, 2, 3, 9, and 10). By applying a voltage of appropriate polarity across the electrical conductors of a particular logic cell a “1” state can be “written” or created. When a voltage of sufficient magnitude is applied across the volume of the molecularly doped polymer layer or film located between two electrical conductors (i.e. from the electrical conductors 210 and 212 as illustrated in FIG. 2), an electric field is formed. This electric field results in charge injection (electrons or holes) from one of the electrical conductors to the acceptor or donor molecules or functional groups, of the organic dopant in the molecularly doped polymer layer or film. During the writing state, the electrical charge can migrate in response to the electric field by “hopping” from one molecule to an adjacent molecule or functional group.

When the voltage is removed the charge becomes substantially “trapped” or localized on the organic dopants.

Once a “1” state has been written or created in a logic cell the logic cell may be interrogated or “read” by utilizing a voltage impulse across the electrical conductors of the logic cell and time resolving the polarization current as shown in FIG. 12. Typically the magnitude of the impulse voltage is less than the magnitude of the writing pulse to minimize the injection of additional charge into the logic cell. The physical displacement of the trapped charge, responding to the voltage impulse 1202, generates a measurable current as shown in FIG. 12. Logic cells that have not been “written” will exhibit a smaller current than logic cells that have been “written.” The current before charge is injected represents a “0” for an unwritten cell, and the current after charge is injected represents a “1” for a written cell as shown in FIG. 12. The particular magnitude and transient response or time decay of the current will depend, for example, on the length of time that charge injection is permitted, the particular organic dopant utilized, the dopant concentration, the thickness of the molecularly doped polymer layer, and the presence or absence of a thin dielectric film to name a few factors. The access time for this type of doped polymer memory device will depend on the width of the voltage impulse used and the response of the charge sensitive amplifier (not shown) used to measure the current.

A logic cell in this type of doped polymer memory device can also be erased (i.e. the state changed from a “1” to a “0”). In one embodiment, such erasure occurs by applying a voltage pulse having an erasing polarity (typically a polarity opposite to that used to write a bit to the logic cell) across the electrical conductors of the particular logic cell being erased. The particular magnitude and erasing time utilized will depend, for example, on the organic dopant utilized, the charge mobility of the system, the thickness of the molecularly doped polymer layer, and the presence or absence of a thin dielectric film to name a few factors. Typically, the applied voltage will be less than the writing voltage to minimize injection of any stray charge.

In an alternate embodiment, erasure can be accomplished by exposing the molecularly doped polymer layer to light. The particular wavelength utilized will depend, for example, on the particular dopant and binder material utilized. In this embodiment, one of the electrical conductors is a substantially optically transparent, electrically conductive material such as indium tin oxide. A focused light beam may be utilized to selectively expose a logic cell to light. However, any of the other standard techniques such as lasers or shadow masks may also be utilized to expose selective logic cells in this embodiment.

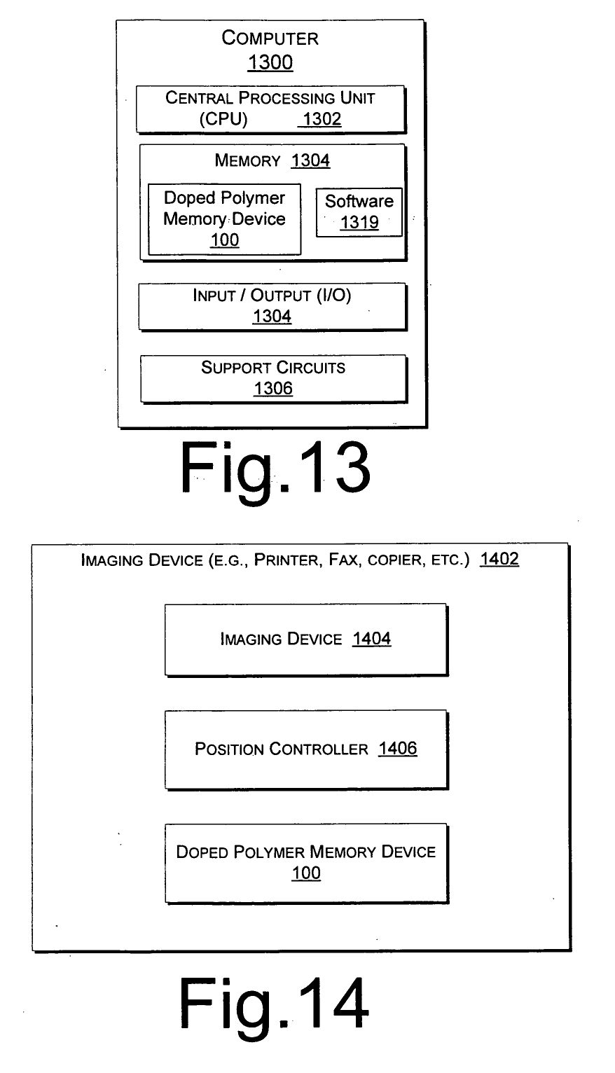

FIG. 13 illustrates one embodiment of a computer 1300 that includes the doped polymer memory device 100. One embodiment of the doped polymer memory device 100 is described relative to FIG. 2. The computer 1300 comprises a central processing unit (CPU) 1302, a memory 1304 (that includes the doped polymer memory device 100), support circuits 1306 and input/output (I/O) circuits 1308. While the doped polymer memory device 100 is shown within the memory 1304, during many computer operations the actual data and computer instructions corresponding to the doped polymer memory device may be included in one or more of the CPU 1302, the memory 1304, the I/O circuits 1308, and other computer or computer network locations.

The CPU 1302 acts as a processor for a general purpose computer which when programmed by executing software 1319 contained in memory 1304 becomes a specific purpose computer for controlling the hardware components of the CPU 1302. The memory 1304 includes the doped polymer memory device in addition to other types of memories such as Random Access Memory (RAM) or Read Only Memory (ROM). The I/O circuits comprise well known displays for output of information and keyboards, mouse, track ball, or input of information that can allow for programming of the computer 1300 to control the process performed by the CPU 1312. The support circuits 1306 are well known in the art and include circuits such as cache, clocks, power supplies, and the like. The memory 1314 contains control software that when executed by the CPU 1302 enables the computer 1300 to digitally control the various components of the process portion 1302.

Referring to FIG. 14, there are a variety of applications that can use the doped polymer memory device 100. One embodiment of these applications is an imaging device 1402. The imaging device 1402 may include such devices as a printer, a fax machine, a copier, a camera, and a scanner. One embodiment of the imaging device 1402 includes an imaging mechanism 1404, a position controller 1406, and the doped polymer memory device 100. One embodiment of the imaging mechanism 1404 provides for scanning a photograph, document, etc. into an image that can be stored as data into the doped polymer memory device 100 and/or further processed. Another embodiment of the imaging mechanism 1404 provides for printing a document based on data stored in the doped polymer memory device 100. The position controller 1406 controls where a print head (for a printer) or copying mechanism (for a copier or scanner) is relative to a media such as a piece of paper or other document. A variety of printer types are known, and are categorized under such types as inkjet. The printer types and printing operation have been described in a variety of documents, and will not be further detailed herein.

For those doped polymer memory devices 100 that are designed to include active semiconductor devices such as transistors, the substrate may be formed from, for example, silicon, gallium arsenide, indium phosphide, and silicon carbide to name a few. Active devices will be formed utilizing conventional semiconductor processing equipment. Other substrate materials including plastics can also be utilized, depending on the particular application in which the doped polymer memory device will be used. For example various glasses, plastics, polymer layers, elastomeric layers, aluminum oxide and other inorganic dielectrics can be utilized. Forming the substrates from a flexible material (such as certain plastics or polymers) allows for the substrate to conform to some desired shape or application. In addition, flexible substrates can be folded, rolled, or in some other manner configured to reduce the dimensions of the doped polymer memory devices 100 and/or other devices located on the substrate. In addition, metals such as aluminum and tantalum can be utilized.

For those doped polymer memory device 100 that are designed to include non-semiconductor substrates, active devices can also be formed on these materials utilizing techniques such as amorphous silicon or polysilicon thin film transistor (TFT) processes or processes used to produce organic or polymer based active devices. Accordingly, the present disclosure is not intended to be limited to those devices fabricated in silicon semiconductor materials, but will include those devices fabricated in one or more of the available semiconductor materials and technologies known in the art.

The process of creating the first layer of electrical conductors 1093 may consist of sputter deposition, electron beam evaporation, thermal evaporation, or chemical vapor deposition of either metals or alloys and will depend on the particular material chosen for the electrical conductors. Conductive materials such as polyaniline, polypyrrole, pentacene, thiophene compounds, or conductive inks, may utilize any of the techniques used to create thin organic films. For example, screen printing, spin coating, dip coating, spray coating, ink jet deposition and, thermal evaporation are techniques that may be used.

The doped polymer memory device can be fabricated in a variety of dimensions down to, and including, the nanoscale. Well known fabrication techniques can be used to fabricate the doped polymer memory devices having dimensions larger than nanoscale. Patterning of the electrical conductors is accomplished by any of the generally available photolithographic techniques utilized in semiconductor processing. For smaller, more densely packed devices and array of devices, nanoscale fabrication techniques can be used and represent an example of fabricating the disclosed doped polymer memory device. Depending on the particular doped polymer memory device being fabricated, the electrical contacts may be created either on a substrate or directly on the molecularly doped polymer layer or film. Depending on the particular material chosen, nanoimprint lithography can be used to fabricate the doped polymer memory devices 100. One illustrative co-pending application that describes nanoimprint lithography devices, and the associated process to make such devices, is U.S. patent application Ser. No. 10/423063, entitled “Sensor Produced Using Imprint Lithogtraphy” to James Stasiak et al. filed Apr. 24, 2003 (incorporated herein by reference).

The process of creating a molecularly doped polymer layer including an organic dopant 1094 will depend on the particular binder and organic dopant chosen. The particular binder and organic dopant chosen will depend, for example, on the particular electronic properties desired, the environment in which the device will be used, and whether a thin dielectric film will be utilized. Depending on the particular binder chosen the appropriate solvents are utilized that provide sufficient solubility for both the binder and the organic dopant as well as providing appropriate viscosity for the particular coating or casting process chosen.

An exemplary process for creating a semiconducting polymer layer uses HPLC grade tetrahydrofuran (THF) as a solvent to dissolve the binder bisphenol-A-polycarbonate and a mono-substituted diphenylhydrazone compound (DPH) in appropriate concentrations to obtain the desired electrical properties. If a substrate is utilized, as shown, for example, in FIGS. 2 and 3, then the composition and properties of the substrate are also taken into consideration, in order to obtain good adhesion between the substrate and the semiconductor polymer layer, as well as the electrical conductors and the semiconductor polymer layer. Adhesion promoters or surface modification may also be utilized. In addition, a planarizing layer may also be utilized, for example, when electrical conductors are formed on, rather than in, the substrate. The process of creating a second or multilayer molecularly doped polymer layer or film 1095, for those applications utilizing such a structure, can be the same or similar as the process used to create the first layer, depending on whether the binder or organic dopant is the same as that used for the first layer.

The process of forming a first 1096 dielectric thin film, will depend on the particular material chosen, and may consist of, for example, sputter deposition, chemical vapor deposition, spin coating, or electrochemical oxidation. For example, tantalum electrical conductors may be deposited using conventional sputtering or electron beam deposition techniques. After the tantalum is deposited a thin tantalum oxide layer may be formed electrochemically. This process may be performed prior to or after photolithographic processing to define the electrical conductors. Another embodiment may utilize a thin silicon oxide layer deposited on the electrical conductors or on the molecularly doped polymer layer or film depending on which electrical conductor is chosen to have the thin dielectric film. A thin silicon oxide film may be deposited by any of a wide range of techniques, such as sputter deposition, chemical vapor deposition, or spin coating of a spin on glass material, to name a few. Still another embodiment may utilize a thin non-conducting polymer layer, such as the undoped binder polymer, deposited on the appropriate electrical conductors. Other embodiments may utilize self assembled monolayers or silane coupling agents to produce a thin dielectric film.

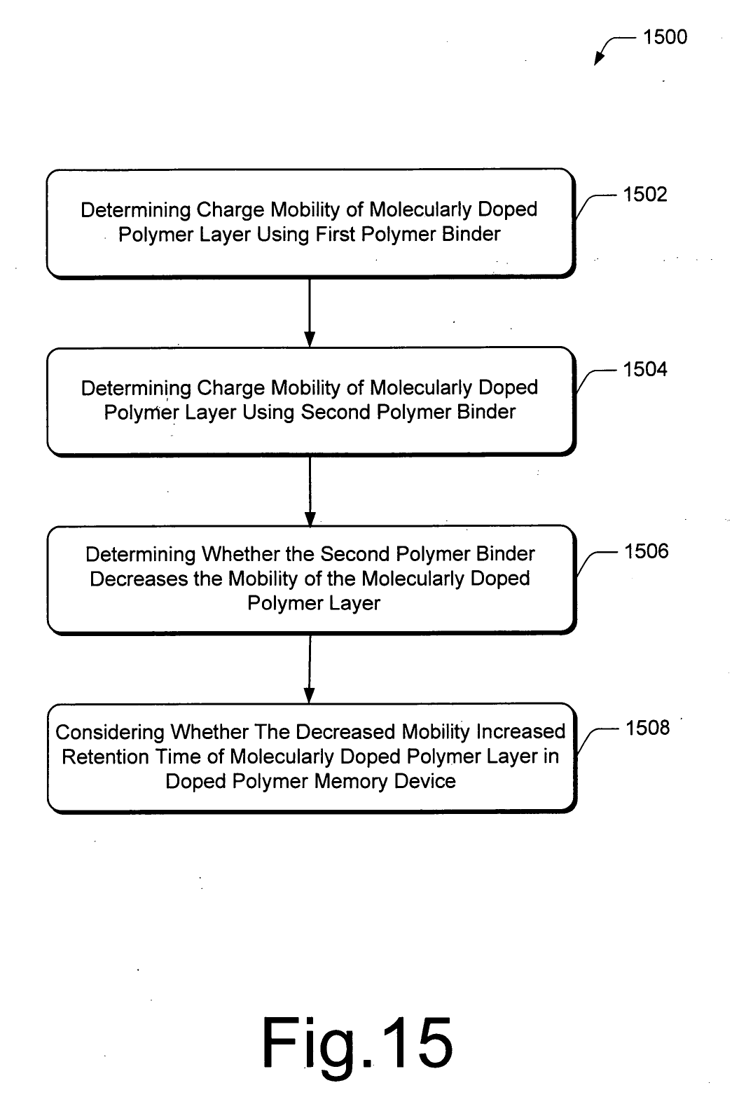

FIG. 15 shows one version of a mobility comparison process 1500 that can be used to design a doped polymer memory device 100. The mobility comparison process 1500 starts with 1502 in which the charge mobility of the molecularly doped polymer layer 114 is considered using a first polymer binder. In 1504, the charge mobility of the molecularly doped polymer layer 114 is considered using a second polymer binder. In 1506, it is determined whether the second polymer binder decreases the mobility of the molecularly doped polymer layer compared with the first polymer binder. Based on 1508, it is considered whether the decreased mobility results in an increased retention time of the molecularly doped polymer layer within the doped polymer memory device. The mobility comparison process 1500 can be repeated for a variety of polymer binders to determine a desired doped polymer layer for a doped polymer memory device 100. This process can be performed using a computer to derived a desired retention time, or alternatively using a relatively few manual calculations.

Within this disclosure, the term “doped polymer memory device” 100 is intended to apply to and include flash memory devices. Flash memory devices (some of which are commercially available) rely on the presence or absence of stored charge to represent stored bits. As such, the different embodiments of the doped polymer memory devices 100 that also rely on the presence or as described within this disclosure can be considered as analogous to the flash memory devices.

From a fabrication aspect, within the different embodiments of the doped polymer memory devices 100, the molecular layers can be combined using silicon elements. The molecular layers of the doped polymer memory devices 100 would be provided with appropriate charge trapping characteristics. In this manner, the embodiments of doped polymer memory devices 100 can compete directly with flash memory devices that are currently commercially available.

Although the invention is described in language specific to structural features and methological steps, it is to be understood that the inventions defined in the appended claims are not necessarily limited to the specific features or steps described. Rather, the specific features and steps disclosed represent preferred forms of implementing the claimed invention.

1. A doped polymer memory device comprising:
a molecularly doped polymer layer that includes a binder and one or more molecular dopants, wherein the combination of the binder and the one or more dopants predictably modifies the polarizability of the molecularly doped polymer layer as compared to the polarizability of the binder alone to enhance the retention time of the doped polymer memory device, and wherein the polarizability of the molecularly doped polymer layer is enhanced by changing the dipole moment of the binder and/or the dipole moment of the dopant in the molecularly doped polymer layer, and wherein the retention time of the molecularly doped polymer layer is enhanced at least partially by modifying dipole side groups of the binder to modify the unit dipole moment of the binder.

2. The apparatus of claim 1, wherein the binder comprises a polymer.

3. The apparatus of claim 2, wherein the polymer binder comprises a polystyrene.

4. The apparatus of claim 1, wherein the doped polymer memory device includes at least one electrode.

5. The apparatus of claim 1, further comprising a pair of electrodes that are arranged across the molecularly doped polymer layer, wherein relative biasing between the pair of electrodes provide an increase in electrons or holes traversing the molecularly doped polymer layer using a mechanism of hopping between distinct dopant material sites as compared to relative lack of biasing between the pair of electrodes.

6. The apparatus of claim 1, wherein dipoles that exist around a charge of the memory cell will shift in response to changes to the charge, wherein the energy of the charge is lowered, and wherein the retention time is increased.

7. The apparatus of claim 1, wherein the molecular dopant comprises a diethylamino-benzaldehyde diphenyl hydrazone (DEH) molecule.

8. The apparatus of claim 1, wherein the dopant is dispersed substantially uniformly within the binder to form a compound.

9. The apparatus of claim 1, further comprising detecting memory cells that have a trapped charge from memory cells that do not have a trapped charge.

10. The apparatus of claim 9, wherein the detection comprises maintaining the charge for a sufficiently duration to provide accurate detection.

11. The apparatus of claim 1, wherein the molecularly doped polymer layer is arranged in a cross-bar architecture.

12. The apparatus of claim 1, wherein the doped polymer memory device includes a transistor.

13. The apparatus of claim 1, wherein the doped polymer memory device includes a resistor.

14. The apparatus of claim 1, wherein the doped polymer memory device includes a capacitor.

15. The apparatus of claim 1, wherein the doped polymer memory device is electrically tunable.

16. The apparatus of claim 1, wherein the doped polymer memory device is optically tunable.

17. The apparatus of claim 1, wherein the doped polymer memory device includes a substrate upon which the molecularly doped polymer layer is deposited.

18. The apparatus of claim 1, wherein the doped polymer memory device includes a plastic substrate upon which the molecularly doped polymer layer is deposited.

19. The apparatus of claim 1, wherein the doped polymer memory device includes a flexible substrate upon which the molecularly doped polymer layer is deposited.

20. An apparatus comprising:
a doped polymer memory device including:
a molecularly doped polymer layer that includes a binder and a dopant, and
an additional dopant that is added to the molecularly doped polymer layer, the additional dopant is selected to modify the polarizability of the molecularly doped polymer layer in a manner that enhances the retention time of the doped polymer memory device as compared to the molecularly doped polymer layer with the binder and the dopant, but without the additional dopant.

21. The apparatus of claim 20, wherein the binder comprises a polymer binder.

22. The apparatus of claim 20, wherein the polymer binder comprises a polycarbonate.

23. The apparatus of claim 20, wherein the polymer binder comprises a polystyrene.

24. The apparatus of claim 20, wherein the doped polymer memory device includes one electrode.

25. The apparatus of claim 20, wherein the doped polymer memory device includes a plurality of electrodes.

26. The apparatus of claim 20, wherein the polarizability of the molecularly doped polymer layer is enhanced by adding dipole side groups to the polymer binder.

27. The apparatus of claim 20, wherein the added molecules have electrical dipole moments.

28. The apparatus of claim 20, wherein the dipole moments of the added molecules will shift in response to the charge in the memory cell and reduce the energy of the charge.

29. The apparatus of claim 20, wherein each dipole that exists around the charge that is positioned in the memory cell will shift in response to the charge, will lower the energy of the charge, and will increase its retention time.

30. The apparatus of claim 20, wherein the additional dopant comprises a diethylamino-benzaldehyde diphenyl hydrazone (DEH) molecule.

31. The apparatus of claim 20, wherein the additional dopant is dispersed uniformly within the polymer binder to form a compound.

32. The apparatus of claim 20, further comprising detecting between memory bits/memory cells that have a trapped charge from cells that do not have a trapped charge.

33. The apparatus of claim 20, wherein the detection comprises maintaining the charge for a sufficiently duration to provide accurate detection.

34. The apparatus of claim 20, wherein the molecularly doped polymer layer is included in a cross-bar architecture.

35. The apparatus of claim 20, wherein the doped polymer memory device includes a memory device.

36. The apparatus of claim 20, wherein the doped polymer memory device includes a transistor.

37. The apparatus of claim 20, wherein the doped polymer memory device includes a resistor.

38. The apparatus of claim 20, wherein the doped polymer memory device includes a capacitor.

39. The apparatus of claim 20, wherein the doped polymer memory device is electrically tunable.

40. The apparatus of claim 20, wherein the doped polymer memory device is optically tunable.

41. A method comprising:
fabricating a doped polymer memory device, the fabrication includes:
doping a molecularly doped polymer layer within the doped polymer memory device with a binder and a dopant in a manner to modify polarizability of the molecularly doped polymer layer to enhance the retention time of the doped polymer memory device.

42. The method of claim 41, wherein the modification of the molecularly doped polymer layer is achieved by modifying the polymer in the molecularly doped polymer layer.

43. The method of claim 41, wherein the modification of the molecularly doped polymer layer includes chemically altering the molecularly doped polymer layer.

44. The method of claim 41, further comprising:
depositing a first electrode;
depositing the molecularly doped polymer layer; and
depositing a second electrode.

45. The method of claim 41, further comprising:
depositing a first electrode;
depositing the molecularly doped polymer layer.

46. The method of claim 41, further comprising detecting between memory bits/memory cells that have a trapped charge from cells that do not have a trapped charge.

47. The method of claim 41, wherein the detection includes maintaining the charge for a sufficiently duration to provide accurate the detection.

48. The method of claim 41, wherein there are thermal fluctuations that can influence a trapping event, wherein the charge, if it is not charged deeply enough on the molecule, will migrate under thermal fluctuations and become untrapped.

49. A method for designing a polymer for a molecularly doped polymer layer to increase the retention time in a doped polymer memory device, comprising:
determining the mobility of the molecularly doped polymer layer that is designed by using a first polymer binder;
determining the mobility of the molecularly doped polymer layer that is designed by using a second polymer binder;
determining whether there is a reduced mobility for the molecularly doped polymer layer using the second polymer binder compared to the molecularly doped polymer layer using the first polymer binder; and
considering whether the reduced mobility acts to increase a retention time for the molecularly doped polymer layer in the doped polymer memory device.

50. The method of claim 49, wherein a reduced mobility that for the molecularly doped polymer layer using the second polymer binder compared to the molecularly doped polymer layer using the first polymer binder results because a measurement of the dipole moment indicates the mobility.

51. The method of claim 49, wherein in systems where the polymer binder has large dipole moments, the charge tends to be influenced by the dipole moment, such that the larger the dipole moment, the less mobile the charge.

52. A method comprising:
fabricating a doped polymer memory device, the fabricating includes:
forming a molecularly doped polymer layer within the doped polymer memory device, the molecularly doped polymer layer including a binder and a dopant, and
adding an additional dopant to the molecularly doped polymer layer in a manner to modify a polarizability of the molecularly doped polymer layer, wherein the modifying the polarizability enhances the retention time of the doped polymer memory device.

53. The method of claim 52, further comprising:
depositing a first electrode;
depositing the molecularly doped polymer layer; and
depositing a second electrode.

54. The method of claim 52, further comprising:
depositing a first electrode;
depositing the molecularly doped polymer layer.

55. The method of claim 52, wherein the doped polymer memory device is fabricated on a substrate.

56. The method of claim 52, wherein the doped polymer memory device is fabricated on a plastic substrate.

57. The method of claim 52, wherein the doped polymer memory device is fabricated on a flexible substrate.

58. The method of claim 52, further comprising detecting between memory bits/memory cells that have a trapped charge from cells that do not have a trapped charge.

59. The method of claim 52, wherein the detection includes maintaining the charge for a sufficiently duration to provide accurate the detection.

60. The method of claim 52, wherein there are thermal fluctuations that can influence a trapping event, wherein the charge, if it is not charged deeply enough on the molecule, will migrate under thermal fluctuations and become untrapped.

61. An apparatus comprising:
a flash memory including a doped polymer memory device including:
a molecularly doped polymer layer that includes a binder and a dopant, the combination of the binder and the dopant modifies the polarizability of the molecularly doped polymer layer in a manner that enhances the retention time of the doped polymer memory device at least partially by modifying dipole side groups of the binder to modify the unit dipole moment of the binder.

62. The apparatus of claim 61, wherein the doped polymer memory device includes a substrate upon which the molecularly doped polymer layer is deposited.

63. The apparatus of claim 61, wherein the doped polymer memory device includes a plastic substrate upon which the molecularly doped polymer layer is deposited.

64. The apparatus of claim 61, wherein the doped polymer memory device includes a flexible substrate upon which the molecularly doped polymer layer is deposited.
